(19) United States
(12) Patent Application Publication
(10) Pub. No.: US 2015/0010034 A1
(43) Pub. Date: Jan. 8, 2015

(54) SHORT CAVITY SURFACE EMITTING LASER WITH DOUBLE HIGH CONTRAST GRATINGS WITH AND WITHOUT AIRGAP

(71) Applicant: THE REGENTS OF THE UNIVERSITY OF CALIFORNIA, Oakland, CA (US)

(72) Inventors: Connie Chang-Hasnain, Palo Alto, CA (US); Li Zhu, Richmond, CA (US); Yi Rao, El Cerrito, CA (US)

(73) Assignee: THE REGENTS OF THE UNIVERSITY OF CALIFORNIA, Oakland, CA (US)

(21) Appl. No.: 14/329,710

(22) Filed: Jul. 11, 2014

Related U.S. Application Data
(63) Continuation of application No. PCT/US2013/022322, filed on Jan. 18, 2013.
(60) Provisional application No. 61/588,914, filed on Jan. 20, 2012.

(51) Int. Cl. H01S 5/183; H01S 5/32; H01S 5/34

(52) U.S. Cl. CPC H01S 5/18363; H01S 5/34; H01S 5/32
USPC 372/50.124

(57) ABSTRACT

A short-cavity semiconductor laser heterostructure, such as a vertical-cavity surface emitting laser (VCSEL) comprising a laser cavity having upper and lower surfaces and an active region disposed between the upper and lower surfaces for generating light and emitting light substantially perpendicular to the upper surface of the cavity, an upper high contrast grating (HGC) mirror disposed adjacent to the upper surface of the laser cavity, and a lower HCG mirror disposed adjacent to the lower surface of the laser cavity.

### CROSS-REFERENCE TO RELATED APPLICATIONS

This application is a 35 U.S.C. §111(a) continuation of PCT international application number PCT/US2013/022322 filed on Jan. 18, 2013, incorporated herein by reference in its entirety, which claims priority to, and the benefit of, U.S. provisional patent application Ser. No. 61/588,914 filed on Jan. 20, 2012, incorporated herein by reference in its entirety.

The above-referenced PCT international application was published as PCT International Publication No. WO 2013/110004 on Jul. 25, 2013, and is incorporated herein by reference in its entirety.

### STATEMENT REGARDING FEDERALLY SPONSORED RESEARCH OR DEVELOPMENT

Not Applicable

### INCORPORATION-BY-REFERENCE OF COMPUTER PROGRAM APPENDIX

Not Applicable

### NOTICE OF MATERIAL SUBJECT TO COPYRIGHT PROTECTION

A portion of the material in this patent document is subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. §1.14.

### BACKGROUND OF THE INVENTION

1. Field of the Invention

This invention pertains generally to surface emitting lasers, and more particularly to vertical cavity surface emitting lasers.

2. Description of Related Art

The vertical-cavity surface-emitting laser (VCSEL), is a type of semiconductor laser diode with laser beam emission perpendicular from the top surface, contrary to conventional edge-emitting semiconductor lasers (also know as in-plane lasers), which emit from surfaces formed by cleaving the individual chip out of a wafer. VCSEL laser resonators available in the art generally comprise of two distributed Bragg reflector (DBR) mirrors parallel to the wafer surface, with an active region comprising one or more quantum wells for the laser light generation in between.

VCSELs are a very promising low cost and low power consumption laser source for metro area access networks, PON applications, active optical cables and other datacom links. In particular, VCSELs emitting in the 1.3˜1.6 um wavelength range are of interest for longer range wavelength-division-multiplexed (WDM) and optical interconnects. Silicon transparency of long wavelength VCSEL makes it an ideal light source silicon photonic circuit.

Additionally it is desirable to have wavelength tunable VCSELs for WDM-PON and datacenter applications. However, tunable VCSELs available in the art have limited wavelength tuning ranges. This is due to the use of either one or two distributed Bragg reflectors (DBRs), comprising alternating layers of materials with a low index contrast. The DBR makes the VCSEL cavity have a relatively long effective length, and thus limits its tuning range. This presents even more of a challenge for 1.55 μm HCG VCSELs on an InP platform where the DBRs have even smaller index contrast. Additionally, integrating currently available thick VCSEL structures onto silicon is difficult, because 1) very thick epi-structures induce bowing, strain and defects which reduce the yield of III-V to silicon bonding; 2) very thick epi-structures also prevent conducting the dissipated heat out of the active region effectively.

Accordingly, an object of the present invention is the use of high contrast grating (HCG) mirror-based VCSELs. By electrostatically actuating the high contrast grating (HCG) mirror, the depth of air gap between the HCG and the rest of the structure will be varied, thus allowing for different lasing wavelengths by varying the cavity length.

### BRIEF SUMMARY OF THE INVENTION

An aspect of the present invention is an integrated VCSEL structure leveraging HCGs with or without an air gap from the substrate. Such Short Cavity Surface Emitting Lasers (SC-SEL) can increase the wavelength tunability, reduce the total epi-structure thickness and enable large-scale manufacturing of III-V and silicon heterogeneous integration. The SC-SEL structure of the present invention is highly suitable for high speed modulation due to greatly reduced photon lifetime and electron transit time with the short cavity.

An aspect of the present invention is a vertical-cavity surface-emitting laser (VCSEL) comprising a laser cavity having upper and lower surfaces and an active region disposed between the upper and lower surfaces for generating light; an upper high contrast grating (HGC) mirror disposed adjacent to the upper surface of the laser cavity; and a lower HCG mirror disposed adjacent the lower surface of the laser cavity.

Another aspect is a short-cavity semiconductor laser diode, comprising a laser cavity having upper and lower surfaces and an active region disposed between the upper and lower surfaces for generating light and emitting light substantially perpendicular to the upper surface of the cavity; an upper high contrast grating (HGC) mirror disposed adjacent the upper surface of the laser cavity; and a lower HCG mirror disposed adjacent the lower surface of the laser cavity.

Further aspects of the invention will be brought out in the following portions of the specification, wherein the detailed description is for the purpose of fully disclosing preferred embodiments of the invention without placing limitations thereon.

### BRIEF DESCRIPTION OF THE SEVERAL VIEWS OF THE DRAWING(S)

The invention will be more fully understood by reference to the following drawings which are for illustrative purposes only:

FIG. 1 is a sectional view of a short cavity surface emitting laser (SC-SEL) confined by proton implantation in accordance with the present invention.

FIG. 2 is a sectional view of a SC-SEL confined by quantum well mixing in accordance with the present invention.

FIG. 3 is a sectional view of a wafer design for a tunable PI SC-SEL in accordance with the present invention.

FIG. 4 is a sectional view of a buried heterostructure SC-SEL in accordance with the present invention.

FIG. 5 shows a schematic diagram of an HCG mirror for SC-SEL without an air gap in accordance with the present invention.

FIG. 6 shows a plot of the reflectivity spectrum contour map as a function of grating thickness for the HCG mirror of the present invention.

FIG. 7 shows a plot of the reflection spectrum for a 1.55 μm HCG mirror in accordance with the present invention.

FIG. 8 shows a plot of the detailed high-reflection spectrum for the HCG mirror of the present invention.

FIG. 9 shows a plot of the transmission of the HCG mirror of the present invention with input from the low index plane.

FIG. 10 shows a plot of the transmission spectrum of the double HCG mirror cavity of the present invention.

FIG. 11 is a sectional view of a tunable SC-SEL confined by proton implantation in accordance with the present invention.

FIG. 12 is a sectional view of a tunable SC-SEL confined by quantum well mixing in accordance with the present invention.

FIG. 13 is a plot of the reflection spectrum for the HCG for the tunable SC-SEL of the present invention.

FIG. 14 is a plot of the reflection spectrum as a function of different air gap thicknesses between the HCG and the underlying gain media.

### DETAILED DESCRIPTION OF THE INVENTION

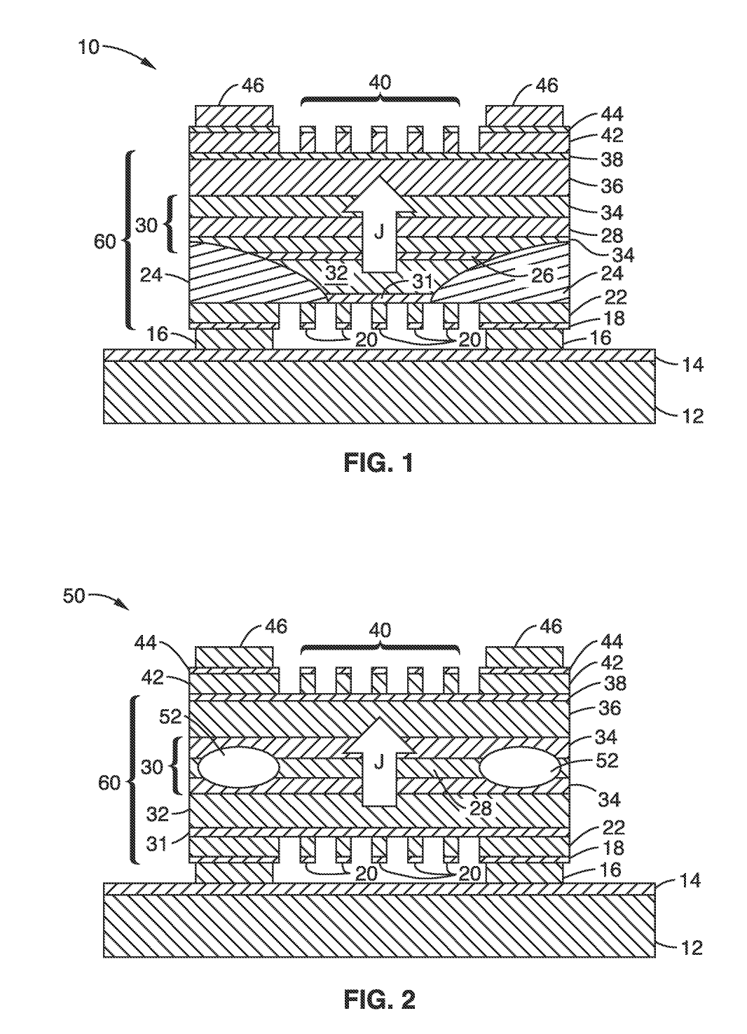

FIG. 1 illustrates a Short Cavity Surface Emitting Laser (SC-SEL) 10 confined by proton implantation. FIG. 2 illustrates a SC-SEL 50 confined by quantum well mixing. The SC-SEL heterostructures 10, 50 comprise an active region 30 disposed between two current spreading layers 32, 36, and lower and upper mirrors 20 and 40. The mirrors 20, 40 comprise high reflection HCGs. In the embodiments shown in FIG. 1 and FIG. 2, the mirrors 20, 40 are positioned directly on the top and bottom of the laser cavity 60 (defined by upper etch stop layer 38, lower etch stop layer 18, and all layers in between) without an air gap from the laser cavity 60, referred herein as an HCG without air gap, or 0-gap HCG. Laser cavity 60 is a short cavity having a thickness less than 3 μm, and preferably ranging between 0.5 μm to 2.5 μm, and is configured for generating lasing light and emitting lasing light perpendicular to the upper surface of the cavity 60.

Active region 30 comprises a central multiple quantum well (MQW) layer 28 disposed between two capping or barrier layers 34. Capping layers 34 are used to confine carriers, and match the cavity 30 thickness to the desired wavelength.

For electrical injection J of each SC-SEL 10, 50, it is beneficial for the SC-SEL structure to provide current and optical confinement in the transverse direction (orthogonal to surface-normal direction).

In the SC-SEL 10 of FIG. 1, current confinement and optical confinement are realized by top and/or backside proton implantation at lateral regions 24. Proton implantation has the effect of making the regions 24 non conductive. Proton implant regions 24 are shown as upwardly diverging regions in FIG. 1, the shape of which may be varied to vary the performance of the device. For example, proton implant regions 24 may extend deeper (i.e. higher) into the strata (encompassing more layers) to make the device faster (with power tradeoff).

In the SC-SEL 50 of FIG. 2, current confinement and optical confinement are realized by lateral quantum well mixing regions 52. Quantum well mixing regions 52 are similarly non-conductive. The shape and size of regions 52 may be varied to vary the performance of the device. For example, quantum well mixing regions 52 may extend beyond the active region or cavity 30, although the effect is achieved primarily within the cavity 30.

It is also appreciated that current confinement and optical confinement may also be realized by other methods or structures known in the art, e.g. via a buried tunnel junction (not shown).

As shown in FIG. 1, a tunnel junction 26 may be disposed between the current spreading layer (e.g. lower current spreading layer 32) and the active region 30 to facilitate efficient carrier injection and reduce free carrier absorption loss and resistivity of p-type materials. It is appreciated that while the tunnel junction may be included in any of the embodiments 10, 50, 70, 100, 120 and 150 of the present invention to improve performance, it may also be optionally omitted to save on fabrication costs.

As shown in FIG. 1 and FIG. 2, HCGs 20, 40 comprise two layers: first, or contact layers 18, 44, and second, or grating bar layers 22, 42, all of which are configured for selective etch-stop at the third layer (lower etch-stop layer 31 and upper etch stop layer 38). However, it is appreciated that the HCGs 20, 40 may comprise additional layers with different refractive indices. In addition, the layer 2 grating bars 22, 42 may be configured to have a smaller width than layer 1 contact layers 18, 44, forming T-shape HCGs 20, 40 (not shown).

In FIG. 1 and FIG. 2, the lower HCGs 20 of SC-SELs 10, and 50 are shown bonded or attached onto a carrier substrate 12 via anodes 16, Carrier substrate 12 may comprise a uniform metal coating 14 (which preferably is the same composition as the cathodes 16. However, this metal layer 14 does not need to be present under the HCG 20. Anodes 46 are coupled to the upper HCGs 40. The carrier substrate 12 may comprise Si, silicon-on-insulator (SOI), AlN, GaN, Al₂O₃, sapphire, SiO₂, Si₃N₄, diamond, metal or other III-V materials. The bonding between III-V and carrier substrate may be achieved by metal-to-metal bonding, molecular bonding or polymer bonding.

The SC-SELs 10 and 50 shown in FIG. 1 and FIG. 2 are illustrated with a gap between the lower HCG 20 and the carrier substrate 12. However, it is appreciated that SC-SELs 10 and 50 may be configured such that the HCG 20 is of a specific height so as to contact the substrate 12 directly.

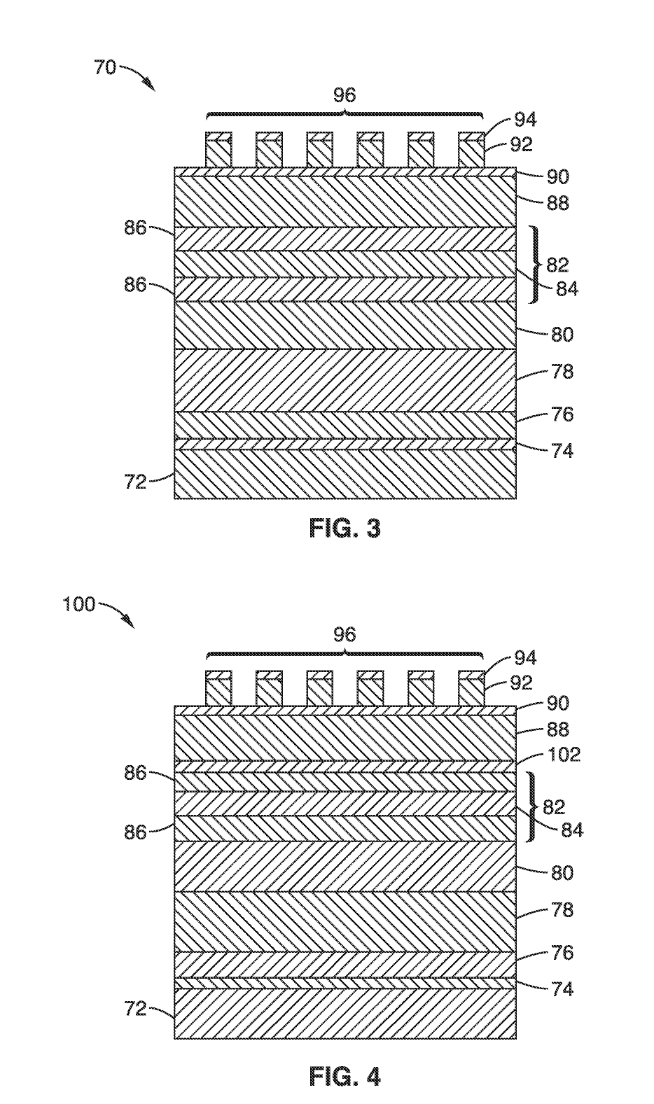

FIG. 3 illustrates a wafer design for a tunable PI SC-SEL 70 in accordance with the present invention. FIG. 4 illustrates a buried heterostructure SC-SEL 100.

The active region 82 may comprise separate carrier-confinement heterostructure with active layers 84 sandwiched in-between carrier-confining barrier or capping layers 86. The total thickness of the active region may be an integer multiple of half-wavelength. The active layers 84 may include single or multiple layers of quantum wells, quantum wires, quantum dots, quantum dots in wells, or simply bulk material. In the embodiments shown in FIG. 3 and FIG. 4, active region 82 comprises a central InGaAs multiple quantum well (MQW) layer 84 separated by capping or barrier layers 86 having a higher bandgap material. The active MQW layer 84 material can comprise any InP, GaAs, GaSb, GaN, and GaP-based materials emitting from 0.3 μm to 10 μm.

The current spreading layers 88 and 80 on top and bottom of the active region 82 may be doped appropriately and may comprise multiple layers of material with different refractive indices to improve optical field concentration at the active layers.

In the tunable PI SC-SEL 70 shown in FIG. 3, the current spreading layers 88 and 80 comprise p-InP layers, and the upper HCG 96 comprises a p⁺-InGaAs anode contact layer 94 and p-InP grating layer 92 that contacts p-InGaAlAs etch stop layer 90.

In the buried heterostructure SC-SEL 100 shown in FIG. 4, the current spreading layers 88 and 80 comprise n-InP layers, and the upper HCG 96 comprises a n⁺-InGaAs anode contact layer 94 and n-InP grating layer 92 that contacts n-InGaAlAs etch stop layer 90.

In both embodiments 70, 100, the lower HCG comprises a p-InP grating layer 76 and P⁺In GaAs cathode contact layer 74 disposed between an i-InGaAlAs sacrificial layer 78 and InP substrate 72. The thickness of the current spreading layers 88, 80 may be chosen such that the round-trip phase of the entire SC-SEL 70, 100 is a multiple of 2π.

As shown in FIG. 4, a tunnel junction (n⁺⁺p⁺⁺-) 102 may be disposed between the current spreading layer 88 and active region 82 to facilitate efficient carrier injection and reduced free carrier absorption loss.

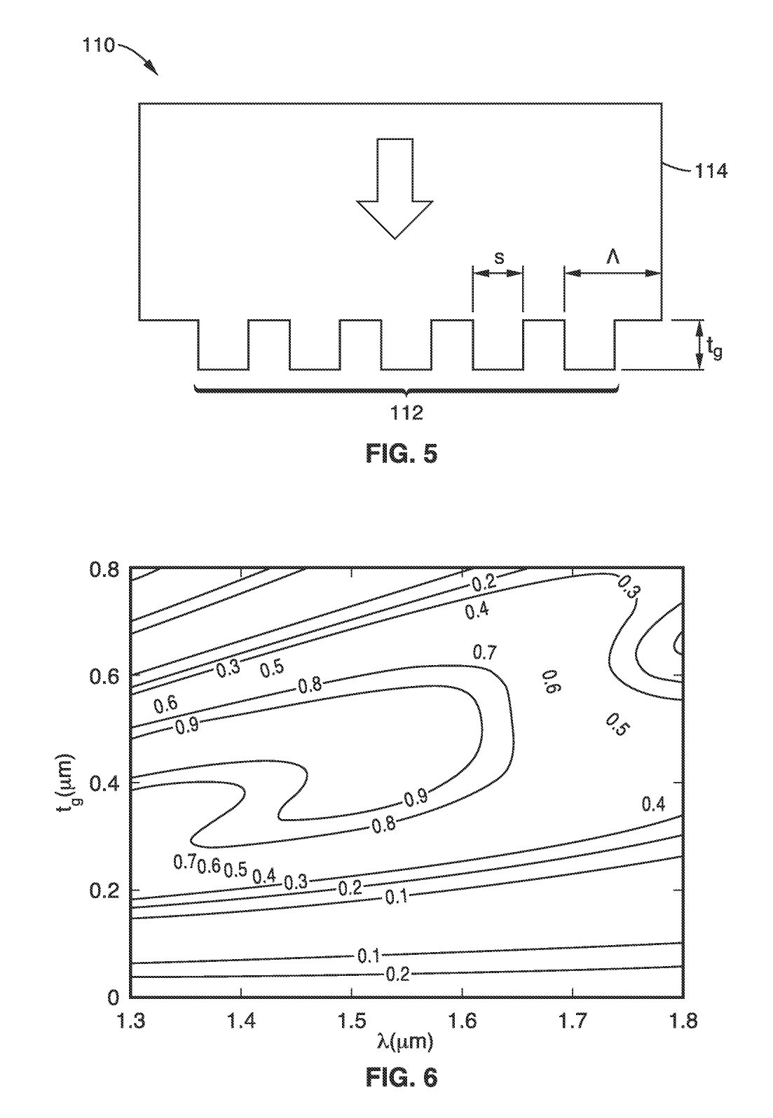

The optical cavity 114 may be configured according to the schematic diagram of the 0-gap HCG mirror SC-SEL 110 of FIG. 5. The 0-gap HCG mirror 112 is a subwavelength grating with high index in the input plane and low index in the output plane. It is defined by three parameters, period Λ, thickness t_{g} and duty cycle η, which is defined by the ratio of the grating bar width s and the period Λ. While FIG. 5 shows five grating bars making up HCG 112, it is appreciated that HCG 112 may comprise any number of grating bars.

FIG. 6 shows a plot of the reflectivity spectrum contour map as a function of different grating thickness t_{g} for the HCG mirror 110.

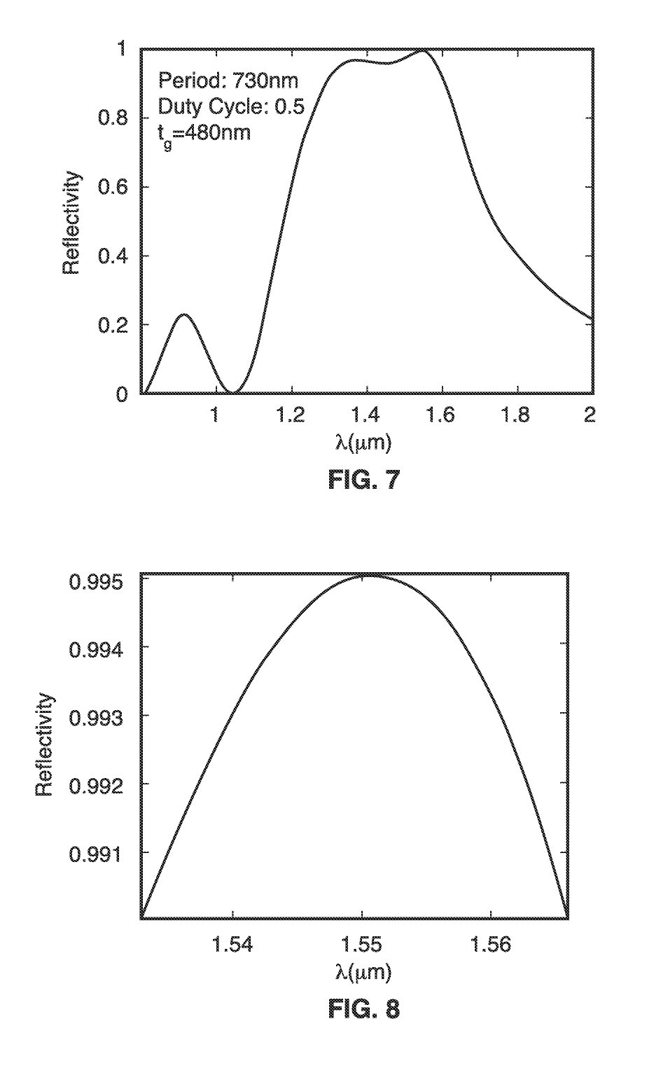

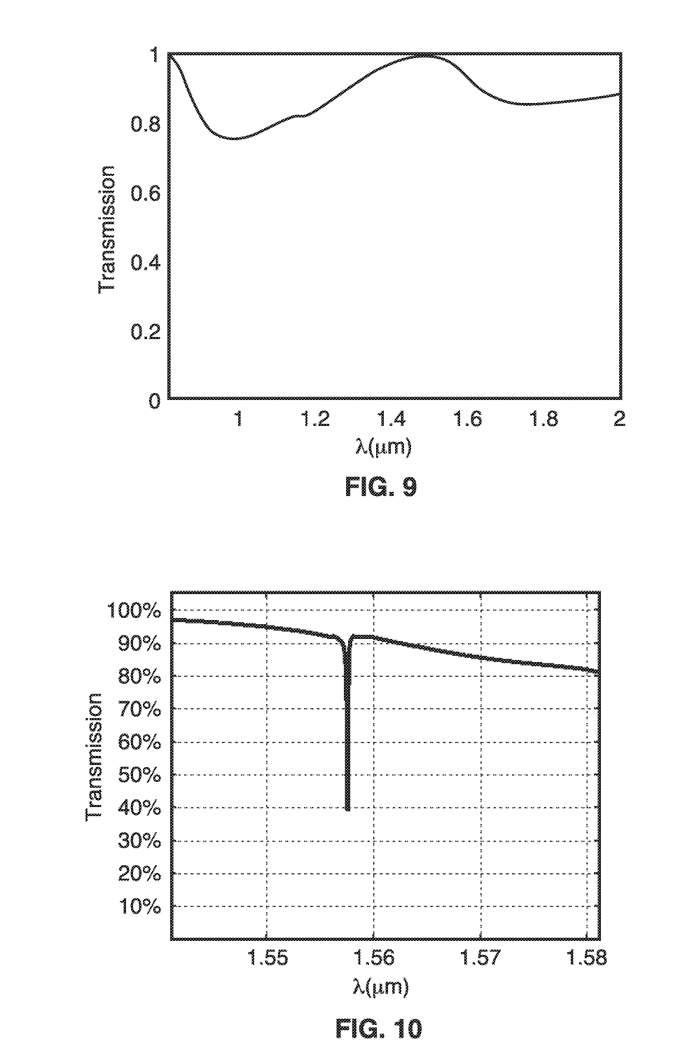

FIG. 7 shows a plot of the reflection spectrum for a 1.55 μm design for the HCG mirror 110, and FIG. 8 shows a plot of the detailed high-reflection spectrum for the HCG mirror 110. FIG. 9 illustrates a plot of the transmission of the HCG mirror of the present invention with input from the low index plane. By sweeping the parameters, the high reflection region (>0.99) is obtained, as shown in FIG. 8.

The cavity 114 may be configured by tuning the phase-matching layer(s) inside the cavity (e.g. current spreading layers and/or barrier layers surrounding the active layers) to make the resonance at 1.55 μm, or any other wavelength between 0.3 μm and 10 μm in principle. The field profile and Q value is therefore obtained by applying FDTD simulation. In the simulation, an external plane wave source is put upon the cavity in the low index surrounding. For the 0-gap HCG mirrors of FIG. 1 through FIG. 5, when the input source is from the low index side, it is highly transparent, as shown in FIG. 9. Therefore, for the cavity 114, the transmission will be high except for the resonance. FIG. 10 shows a plot of the transmission spectrum of the cavity 114, with a narrow dip occurring at the resonance frequency. According to the resonance spectrum, the Q value is 8000.

In order to make the SC-SEL tunable, one mirror may be replaced by a high contrast grating (HCG) with an air gap. The HCG is a subwavelength grating with high index contrast. In design, it is floated in the air and tuned by the MEMS structure.

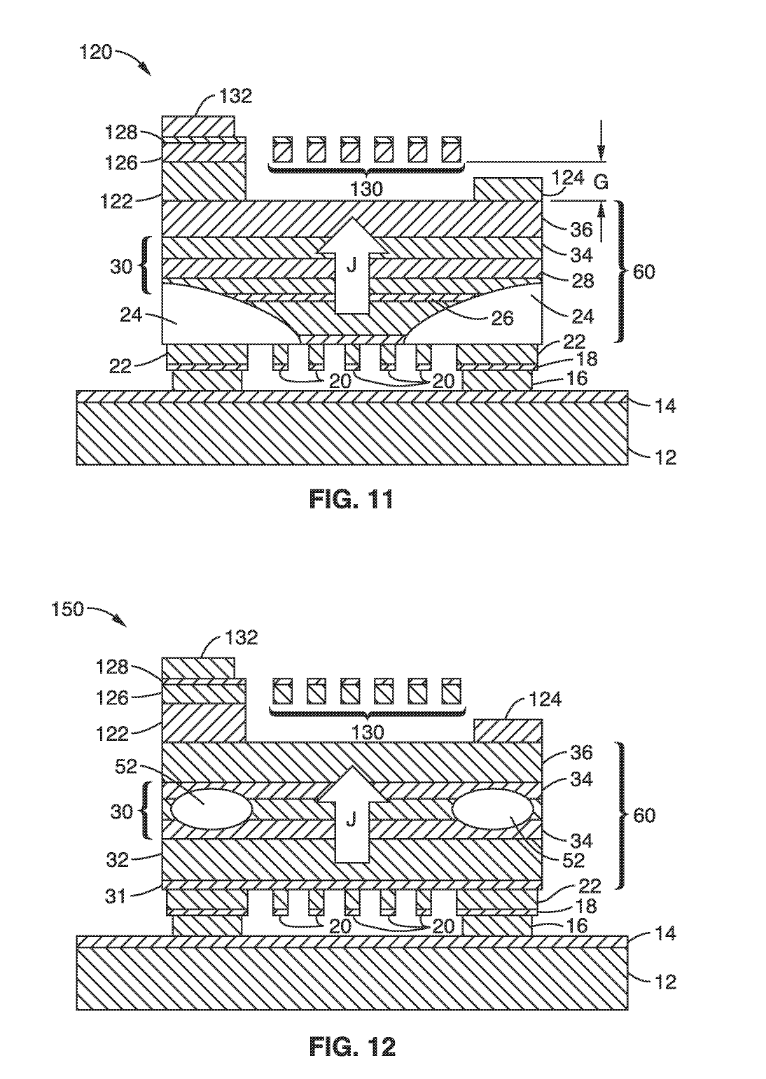

The components of such a tunable VCSEL are shown in FIG. 11 and FIG. 12, where FIG. 11 is a sectional view of a tunable SC-SEL 120 confined by proton implantation regions 24, and FIG. 12 is a sectional view of a tunable SC-SEL 150 confined by quantum well mixing regions 52.

SC-SELs 120 and 150 comprise 0-gap lower HCGs 20 adjacent substrate 12 (which may include metal layer 14) via anodes 16, and upper (open ended) HCGs 130 spaced from the laser cavity 60 by an air-gap G. Sacrificial layer 122 may be used to generate air-gap G from laser cavity 60. As with previously disclosed embodiments, the upper floating HCG 130 may comprise a first, or contact layer 128, and second, or grating bar layer 126. Tuning contact 132 may be provided at contact layer 128, with a cathode 124 being coupled to the laser cavity 60. As with previous embodiments, an active region 30 may comprise an active layer 28 disposed between barrier layers 34, with upper current spreading layer 36 and lower current spreading layer 32 surrounding the active region 30.

The HCGs of the present invention may be configured as an ultra-broad high reflection bandwidth mirror. By varying the gap G between the HCG 130 and the gain material 60, the cavity resonance frequency can be tuned. The tuning of the HCG mirror 130 may be achieved by electrostatic actuation, piezoelectric actuation, thermal actuation or the like.

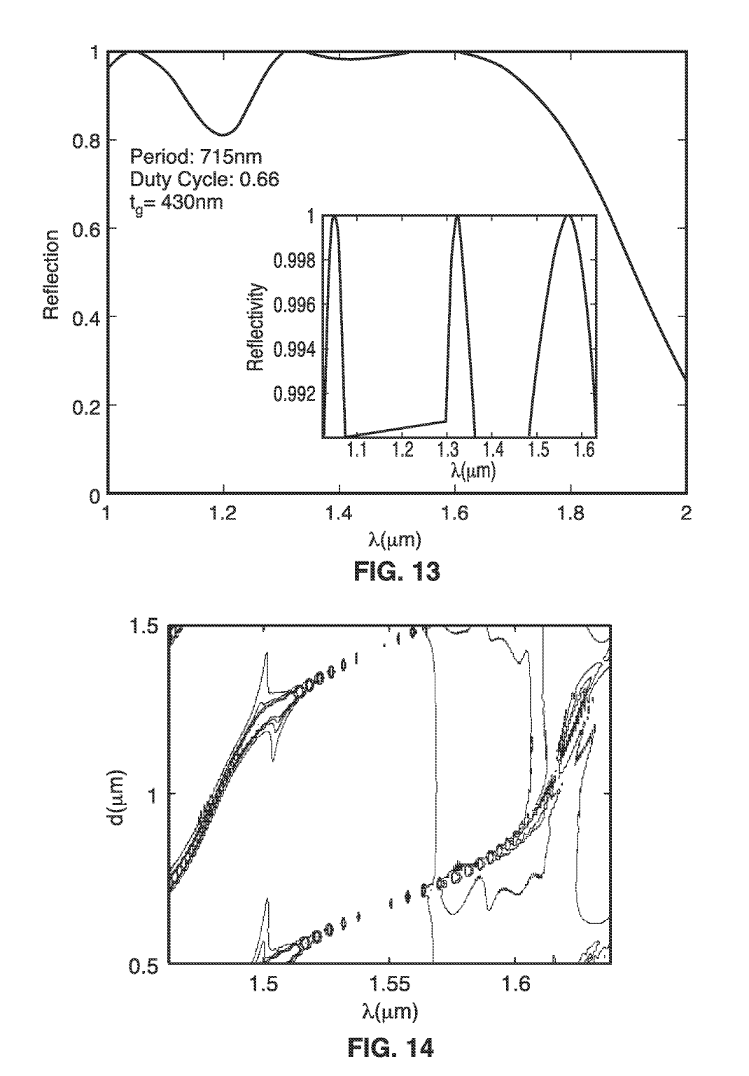

FIG. 13 is a plot of the reflection spectrum for the HCG for the tunable SC-SEL of the present invention.

FIG. 14 shows the reflection spectrum as a function of different air gap thicknesses between the HCG and the underlying gain media. The sharp reflection change presents the resonance. According to this simulation, the tuning efficiency, which is defined as the ratio of the resonance wavelength change and tuning displacement, is 27.4%.

The SC-SELs of the present invention are an ideal light source for Si/III-V heterogeneous integration with low cost, high speed direction modulation and low power consumption, given the nature of the short cavity, high Q and thin Epi-structure. In preferred embodiments, the SC-SELs of the present invention may be used in metro area access networks, PON applications, optical interconnects in data centers.

The tunable SC-SEL of the present invention is an efficient tunable light source that could cover the entire C-band and L-band with a single monolithic epitaxial growth. It can be used as a universal or backup light source in PON applications, and it can also be used as a wavelength switch in data center applications.

As mentioned above, the 0-gap HCG of the present invention has a novel non-reciprocal, asymmetrical reflection behavior. The 0-gap HCG of the present invention may be configured to serve simultaneously as anti-reflection coating for light incident from the low-index medium and as a high reflector for light incident from high-index medium. As such, the SC-SEL can be an ideal light source for Optical-Injection-Locking application, and extinction ratio of large signal modulation can be significantly increased because the reflection from the input light is very small.

In addition, the basic short cavity structure shown above may be configured as a novel resonant cavity detector (RCD) with greatly improved efficiency, or as an efficient photovoltaic device (not shown). For photo detection purpose, the heterostructure design will be largely the same as that of the above-detailed SC-SEL, with the exception of the current spreading layer and active region heterostructure being optimized for better transport of electrons and holes to the contacts. The rest of the fabrication, including current confinement, can be done similarly to the above illustrated SC-SELs. Given the short cavity (which can generally be 40 times thinner than conventional DBR mirrors), the electron transport time is very short, resulting a high speed detector. Wavelength-tunable SC detectors may also be constructed with one of the 0-gap HCGs replaced by HCG similar with air gap Gas shown in FIG. 10 and FIG. 11.

For photovoltaic device or solar cell designs, the active region may be designed such that a broad spectrum of wavelength may be detected, e.g. with chirped quantum well thickness, bulk active region, or periodically stacked quantum wells.

Short cavity lasers are highly desirable for high speed modulation and wide tuning range. Surface emitting topology, on the other hand, facilitates wafer-scale fabrication and testing for low cost manufacturing. The present invention leads to a promising short cavity surface emitting lasers (SC-SEL) with the use of two high contrast gratings (HCGs) for top and bottom reflectors.

The HCGs of the present invention, either with or without an air gap from the substrate, may be applicable for a wide wavelength range from approximately 0.3 μm and approximately 10 μm, and may be fabricated on various substrates, including: InP, GaAs, GaSb, GaN, and GaP substrates.

In addition, the HCGs of the present invention may also be fabricated on silicon-on-insulators. The SC-SEL completely eliminates the difficult growth of thick DBR mirrors. The short cavity promises very high speed (>40 GHz) modulation. It can be heterogeneously integrated on Si for low-cost, low-power consumption applications as well as integration with silicon photonic circuits. The tuning range is expected to be >60 nm, making it desirable for WDM-PON or data center applications.

From the discussion above it will be appreciated that the invention can be embodied in various ways, including the following:

1. A vertical-cavity surface-emitting laser (VCSEL) comprising: a laser cavity having upper and lower surfaces and an active region disposed between the upper and lower surfaces for generating light; an upper high contrast grating (HGC) mirror disposed adjacent the upper surface of the laser cavity; and a lower HCG mirror disposed adjacent the lower surface of the laser cavity.

2. A VCSEL as recited in any of the previous embodiments, wherein both the upper HCG mirror and lower HCG mirror comprise 0-gap mirrors having no air gap between the 0-gap mirror and the upper and lower surfaces of the laser cavity.

3. A VCSEL as recited any of the previous embodiments, wherein the VCSEL is configured to emit light at a fixed wavelength.

4. A VCSEL as recited in any of the previous embodiments, wherein the active region of the laser cavity is configured to generate lasing light at a wavelength between approximately 0.3 μm and approximately 10 μm.

5. A VCSEL as recited any of the previous embodiments, wherein the active region of the laser cavity is configured to generate lasing light at a wavelength of approximately 1.55 μm.

6. A VCSEL as recited in any of the previous embodiments, wherein the upper HCG mirror is open-ended and the lower HCG mirror is coupled to and adjacent a substrate.

7. A VCSEL as recited in any of the previous embodiments, wherein the VCSEL is tunable to emit light at varying wavelengths.

8. A VCSEL as recited in any of the previous embodiments, wherein the upper HCG mirror is spaced apart from the laser cavity via an air gap.

9. A VCSEL as recited in any of the previous embodiments, wherein a resonant frequency of the laser cavity is configured to be tuned by varying the thickness of the air gap.

10. A VCSEL as recited in any of the previous embodiments, wherein the laser cavity comprises a short cavity having a thickness less than 3 μm.

11. A VCSEL as recited in any of the previous embodiments, wherein the laser cavity comprises a short cavity having a thickness ranging between 0.5 μm to 2.5 μm.

12. A VCSEL as recited in any of the previous embodiments, wherein the active region comprises an active layer having one or more quantum well layers.

13. A VCSEL as recited in any of the previous embodiments, wherein the active layer is disposed between carrier confinement layers comprising a high bandgap material.

14. A VCSEL as recited in any of the previous embodiments, wherein the active region is disposed between two current spreading layers.

15. A VCSEL as recited in any of the previous embodiments, further comprising: a tunnel junction layer disposed between the active region and at least one of the current spreading layers.

16. A VCSEL as recited in any of the previous embodiments, wherein current and light within the laser cavity are confined by quantum well mixing within one or more layers of the laser cavity.

17. A VCSEL as recited in any of the previous embodiments, wherein current and light within the laser cavity are confined by proton implantation within layers of the laser cavity

18. A VCSEL as recited in any of the previous embodiments, wherein: the laser cavity comprises a silicon wafer defining the upper and lower surfaces; the upper and lower HCG mirrors being disposed adjacent and substantially parallel to the upper and lower surfaces respectively.

19. A VCSEL as recited in any of the previous embodiments, wherein the upper and lower HCG mirrors comprise an array of structures grown on a substrate.

20. A short-cavity semiconductor laser heterostructure, comprising: a laser cavity having upper and lower surfaces and an active region disposed between the upper and lower surfaces for generating light and emitting light substantially perpendicular to the upper surface of the cavity; an upper high contrast grating (HGC) mirror disposed adjacent the upper surface of the laser cavity; and a lower HCG mirror disposed adjacent the lower surface of the laser cavity.

21. A laser heterostructure as recited in any of the previous embodiments, wherein the laser heterostructure comprises a VCSEL.

22. A laser heterostructure as recited in any of the previous embodiments, wherein the laser heterostructure comprises a fixed wavelength or wavelength tunable structure bonded on an SOI wafer.

23. A laser heterostructure as recited in any of the previous embodiments, wherein the laser heterostructure comprises a slave laser in an optical-injection-locking system.

24. A laser heterostructure as recited in any of the previous embodiments, wherein the laser heterostructure comprises a resonant cavity detector.

25. A laser heterostructure as recited in any of the previous embodiments, wherein the laser heterostructure comprises a photovoltaic device.

26. A laser heterostructure as recited in any of the previous embodiments, wherein both the upper HCG mirror and lower HCG mirror comprise 0-gap mirrors having no air gap between the 0-gap mirror and the upper and lower surfaces of the laser cavity.

27. A laser heterostructure as recited in any of the previous embodiments, wherein the laser heterostructure is configured to emit light at a fixed wavelength.

28. A laser heterostructure as recited in any of the previous embodiments, wherein the upper HCG mirror is open-ended and the lower HCG mirror is coupled to and adjacent a substrate.

29. A laser heterostructure as recited in any of the previous embodiments, wherein the laser heterostructure is tunable to emit light at varying wavelengths.

30. A laser heterostructure as recited in any of the previous embodiments, wherein the upper HCG mirror is spaced apart from the laser cavity via an air gap.

31. A laser heterostructure as recited in any of the previous embodiments, wherein a resonant frequency of the laser cavity is configured to be tuned by varying the thickness of the air gap.

32. A laser heterostructure as recited in any of the previous embodiments, wherein the laser cavity is tunable to a wavelength range between approximately 0.3 μm and approximately 10 μm.

33. A laser heterostructure as recited in any of the previous embodiments, wherein the active region comprises an active layer having one or more quantum well layers.

34. A laser heterostructure as recited in any of the previous embodiments, wherein the active layer is disposed between carrier confinement layers comprising a high bandgap material.

35. A laser heterostructure as recited in claim any of the previous embodiments, wherein the active region is disposed between two current spreading layers.

36. A laser heterostructure as recited in claim any of the previous embodiments, further comprising: a tunnel junction layer disposed between the active region and at least one of the current spreading layers.

37. A laser heterostructure as recited in any of the previous embodiments, wherein current and light within the laser cavity are confined by quantum well mixing within one or more layers of the laser cavity.

38. A laser heterostructure as recited in any of the previous embodiments, wherein current and light within the laser cavity are confined by proton implantation within layers of the laser cavity

39. A laser heterostructure as recited in any of the previous embodiments, wherein: the laser cavity comprises a silicon wafer defining the upper and lower surfaces; the upper and lower HCG mirrors being disposed adjacent and substantially parallel to the wafer surfaces the upper and lower surfaces respectively.

40. A laser heterostructure as recited in any of the previous embodiments, wherein the upper and lower HCG mirrors comprise an array of structures grown on a substrate.

41. A method for emitting light from a short-cavity semiconductor laser heterostructure, comprising: disposing an upper high contrast grating (HGC) mirror adjacent an upper surface of a laser cavity and a lower HCG mirror adjacent a lower surface of the laser cavity; generating light within the laser cavity; and emitting light substantially perpendicular to the upper surface of the cavity.

42. A method as recited in any of the previous embodiments, wherein: both the upper HCG mirror and lower HCG mirror comprise 0-gap mirrors having no air gap between the mirror and the upper and lower surfaces of the laser cavity; and wherein the laser heterostructure is configured to emit light at a fixed wavelength.

43. A method as recited in any of the previous embodiments, wherein the upper HCG mirror is disposed in an open-ended array adjacent the upper surface; and wherein the lower HCG mirror is coupled adjacent to a substrate.

44. A method as recited in any of the previous embodiments, further comprising: tuning the laser heterostructure to emit light at varying wavelengths.

45. A method as recited in any of the previous embodiments, wherein the upper HCG mirror is disposed at a spaced-apart location from the laser cavity via an air gap.

46. A method as recited in any of the previous embodiments, wherein a resonant frequency of the laser cavity is tuned by varying the thickness of the air gap.

47. A method as recited in any of the previous embodiments, wherein the laser cavity is tunable to a wavelength range between approximately 0.3 μm and approximately 10 μm.

48. A short-cavity surface-emitting laser heterostructure comprising a laser cavity between two HCG reflectors as top and bottom mirrors, comprising any of: (a) double 0-gap HCG reflectors as mirrors; or (b) a fixed wavelength or wavelength tunable structure including HCG and 0-gap HCG as top and bottom mirrors; or (c) a fixed wavelength or wavelength tunable structure with current confinement defined by top and/or backside proton implantation; or (d) a fixed wavelength or wavelength tunable structure with current and optical confinement defined by quantum well mixing; or (e) a fixed wavelength or wavelength tunable structure with tunnel junction to reduce the free carrier absorption and resistivity of p-type materials; or (f) an array of fixed wavelength or wavelength tunable structures grown on the same substrate; or (g) a fixed wavelength or wavelength tunable structure bonded on SOI wafer; or (h) a fixed wavelength or wavelength tunable structure as a slave laser in optical-injection-locking system.

49. A short-cavity resonant cavity detector or solar cell heterostructure comprising a laser cavity between two HCG reflectors as top and bottom mirrors, comprising any of: (a) double 0-gap HCG reflectors as mirrors; or (b) a fixed wavelength or wavelength tunable structure including HCG and 0-gap HCG as top and bottom mirrors; or (c) a fixed wavelength or wavelength tunable structure with current confinement defined by top and/or backside proton implantation; or (d) a fixed wavelength or wavelength tunable structure with current and optical confinement defined by quantum well mixing; or (e) a fixed wavelength or wavelength tunable structure with tunnel junction to reduce the free carrier absorption and resistivity of p-type materials; or (f) an array of fixed wavelength or wavelength tunable structures grown on the same substrate; or (g) a fixed wavelength or wavelength tunable structure bonded on SOI wafer; or (h) a fixed wavelength or wavelength tunable structure as a slave laser in optical-injection-locking system.

Although the description above contains many details, these should not be construed as limiting the scope of the invention but as merely providing illustrations of some of the presently preferred embodiments of this invention. Therefore, it will be appreciated that the scope of the present invention fully encompasses other embodiments which may become obvious to those skilled in the art, and that the scope of the present invention is accordingly to be limited by nothing other than the appended claims, in which reference to an element in the singular is not intended to mean “one and only one” unless explicitly so stated, but rather “one or more.” All structural, chemical, and functional equivalents to the elements of the above-described preferred embodiment that are known to those of ordinary skill in the art are expressly incorporated herein by reference and are intended to be encompassed by the present claims. Moreover, it is not necessary for a device or method to address each and every problem sought to be solved by the present invention, for it to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

What is claimed is:

1. A vertical-cavity surface-emitting laser (VCSEL) comprising:
a laser cavity having upper and lower surfaces and an active region disposed between the upper and lower surfaces for generating light;
an upper high contrast grating (HGC) mirror disposed adjacent the upper surface of the laser cavity; and
a lower HCG mirror disposed adjacent the lower surface of the laser cavity.

2. A VCSEL as recited in claim 1, wherein both the upper HCG mirror and lower HCG mirror comprise 0-gap mirrors having no air gap between the O-gap mirror and the upper and lower surfaces of the laser cavity.

3. A VCSEL as recited in claim 1, wherein the VCSEL is configured to emit light at a fixed wavelength.

4. A VCSEL as recited in claim 1, wherein the active region of the laser cavity is configured to generate lasing light at a wavelength between approximately 0.3 μm and approximately 10 μm.

5. A VCSEL as recited in claim 4, wherein the active region of the laser cavity is configured to generate lasing light at a wavelength of approximately 1.55 μm.

6. A VCSEL as recited in claim 1, wherein the upper HCG mirror is open-ended and the lower HCG mirror is coupled to and adjacent a substrate.

7. A VCSEL as recited in claim 6, wherein the VCSEL is tunable to emit light at varying wavelengths.

8. A VCSEL as recited in claim 6, wherein the upper HCG mirror is spaced apart from the laser cavity via an air gap.

9. A VCSEL as recited in claim 8, wherein a resonant frequency of the laser cavity is configured to be tuned by varying the thickness of the air gap.

10. A VCSEL as recited in claim 1, wherein the laser cavity comprises a short cavity having a thickness less than 3 μm.

11. A VCSEL as recited in claim 10, wherein the laser cavity comprises a short cavity having a thickness ranging between 0.5 μm to 2.5 μm.

12. A VCSEL as recited in claim 1, wherein the active region comprises an active layer having one or more quantum well layers.

13. A VCSEL as recited in claim 12, wherein the active layer is disposed between carrier confinement layers comprising a high bandgap material.

14. A VCSEL as recited in claim 12, wherein the active region is disposed between two current spreading layers.

15. A VCSEL as recited in claim 14, further comprising:
a tunnel junction layer disposed between the active region and at least one of the current spreading layers.

16. A VCSEL as recited in claim 1, wherein current and light within the laser cavity are confined by quantum well mixing within one or more layers of the laser cavity.

17. A VCSEL as recited in claim 1, wherein current and light within the laser cavity are confined by proton implantation within layers of the laser cavity

18. A VCSEL as recited in claim 1:
wherein the laser cavity comprises a silicon wafer defining the upper and lower surfaces; and
wherein the upper and lower HCG mirrors are disposed adjacent and substantially parallel to the upper and lower surfaces respectively.

19. A VCSEL as recited in claim 1, wherein the upper and lower HCG mirrors comprise an array of structures grown on a substrate.

20. A short-cavity semiconductor laser heterostructure, comprising:
a laser cavity having upper and lower surfaces and an active region disposed between the upper and lower surfaces for generating light and emitting light substantially perpendicular to the upper surface of the cavity;
an upper high contrast grating (HGC) mirror disposed adjacent the upper surface of the laser cavity; and
a lower HCG mirror disposed adjacent the lower surface of the laser cavity.

21. A laser heterostructure as recited in claim 20, wherein the laser heterostructure comprises a VCSEL.

22. A laser heterostructure as recited in claim 20, wherein the laser heterostructure comprises a fixed wavelength or wavelength tunable structure bonded on an SOI wafer.

23. A laser heterostructure as recited in claim 20, wherein the laser heterostructure comprises a slave laser in an optical-injection-locking system.

24. A laser heterostructure as recited in claim 20, wherein the laser heterostructure comprises a resonant cavity detector.

25. A laser heterostructure as recited in claim 20, wherein the laser heterostructure comprises a photovoltaic device.

26. A laser heterostructure as recited in claim 20, wherein both the upper HCG mirror and lower HCG mirror comprise 0-gap mirrors having no air gap between the 0-gap mirror and the upper and lower surfaces of the laser cavity.

27. A laser heterostructure as recited in claim 21, wherein the laser heterostructure is configured to emit light at a fixed wavelength.

28. A laser heterostructure as recited in claim 21, wherein the upper HCG mirror is open-ended and the lower HCG mirror is coupled to and adjacent a substrate.

29. A laser heterostructure as recited in claim 28, wherein the laser heterostructure is tunable to emit light at varying wavelengths.

30. A laser heterostructure as recited in claim 29, wherein the upper HCG mirror is spaced apart from the laser cavity via an air gap.

31. A laser heterostructure as recited in claim 30, wherein a resonant frequency of the laser cavity is configured to be tuned by varying the thickness of the air gap.

32. A laser heterostructure as recited in claim 30, wherein the laser cavity is tunable to a wavelength range between approximately 0.3 μm and approximately 10 μm.

33. A laser heterostructure as recited in claim 20, wherein the active region comprises an active layer having one or more quantum well layers.

34. A laser heterostructure as recited in claim 33, wherein the active layer is disposed between carrier confinement layers comprising a high bandgap material.

35. A laser heterostructure as recited in claim 33, wherein the active region is disposed between two current spreading layers.

36. A laser heterostructure as recited in claim 35, further comprising:
a tunnel junction layer disposed between the active region and at least one of the current spreading layers.

37. A laser heterostructure as recited in claim 20, wherein current and light within the laser cavity are confined by quantum well mixing within one or more layers of the laser cavity.

38. A laser heterostructure as recited in claim 20, wherein current and light within the laser cavity are confined by proton implantation within layers of the laser cavity

39. A laser heterostructure as recited in claim 20:
wherein the laser cavity comprises a silicon wafer defining the upper and lower surfaces; and
wherein the upper and lower HCG mirrors are disposed adjacent and substantially parallel to the wafer surfaces the upper and lower surfaces respectively.

40. A laser heterostructure as recited in claim 20, wherein the upper and lower HCG mirrors comprise an array of structures grown on a substrate.

41. A method for emitting light from a short-cavity semiconductor laser heterostructure, comprising:
disposing an upper high contrast grating (HGC) mirror adjacent an upper surface of a laser cavity and a lower HCG mirror adjacent a lower surface of the laser cavity;
generating light within the laser cavity; and
emitting light substantially perpendicular to the upper surface of the cavity.

42. A method as recited in claim 41, wherein:
both the upper HCG mirror and lower HCG mirror comprise 0-gap mirrors having no air gap between the mirror and the upper and lower surfaces of the laser cavity; and
wherein the laser heterostructure is configured to emit light at a fixed wavelength.

43. A method as recited in claim 41, wherein the upper HCG mirror is disposed in an open-ended array adjacent the upper surface; and
wherein the lower HCG mirror is coupled adjacent to a substrate.

44. A method as recited in claim 43, further comprising:
tuning the laser heterostructure to emit light at varying wavelengths.

45. A method as recited in claim 44, wherein the upper HCG mirror is disposed at a spaced-apart location from the laser cavity via an air gap.

46. A method as recited in claim 45, wherein a resonant frequency of the laser cavity is tuned by varying the thickness of the air gap.

47. A method as recited in claim 44, wherein the laser cavity is tunable to a wavelength range between approximately 0.3 μm and approximately 10 μm.
